(19) United States
(12) Patent Application Publication
(10) Pub. No.: US 2011/0242740 A1
(43) Pub. Date: Oct. 6, 2011

(54) PORTABLE ELECTRONIC DEVICE WITH SLIDABLE COVER

(75) Inventor: JIN-SIANG GEORGE SEAH, Santa Clara, CA (US)

(73) Assignee: FIH (HONG KONG) LIMITED, Kowloon (HK)

(21) Appl. No.: 12/842,149

(22) Filed: Jul. 23, 2010

(30) Foreign Application Priority Data
Apr. 2, 2010 (CN) 201010138583.6

(51) Int. Cl. H05K 7/00

(52) U.S. Cl. 361/679.01

(57) ABSTRACT

A portable electronic device includes a base, a cover, and an adjusting mechanism. One side of the adjusting mechanism is rotatably attached to the base and the other end of the adjusting mechanism is rotatably attached to the cover. The adjusting mechanism expands during opening. One edge of the cover slides on the base and the other edge of the cover is lifted from the base by the adjusting mechanism.

### BACKGROUND

1. Technical Field

The present disclosure relates to portable electronic devices, especially to a portable electronic device with a sliding cover.

2. Description of related art

Portable electronic devices, such as mobile phones, notebooks, and others, often have a base and a cover with a display. The cover is fixed to the base such that the position of the display can only be adjusted along one axis, causing inconvenience of use.

Therefore, there is room for improvement within the art.

### BRIEF DESCRIPTION OF THE DRAWINGS

Many aspects of the exemplary portable electronic device with adjustable cover can be better understood with reference to the following drawings. The components in the drawings are not necessarily drawn to scale, the emphasis instead being placed upon clearly illustrating the principles of the portable electronic device. Moreover, in the drawings, like reference numerals designate corresponding parts throughout the several views, in which:

FIG. 1 is an exploded, isometric view of an exemplary embodiment of a portable electronic device with a slidable cover;

FIG. 2 is an isometric view of a cover of the portable electronic device;

FIG. 3 is an exploded, isometric view of an adjusting mechanism of the portable electronic device of FIG. 1;

FIG. 4 is an assembled view of the portable electronic device of FIG. 1, shown in an open state;

FIG. 5 is similar to FIG. 4, but viewed from another aspect;

FIG. 6 is similar to FIG. 5, but shown in a closed state.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

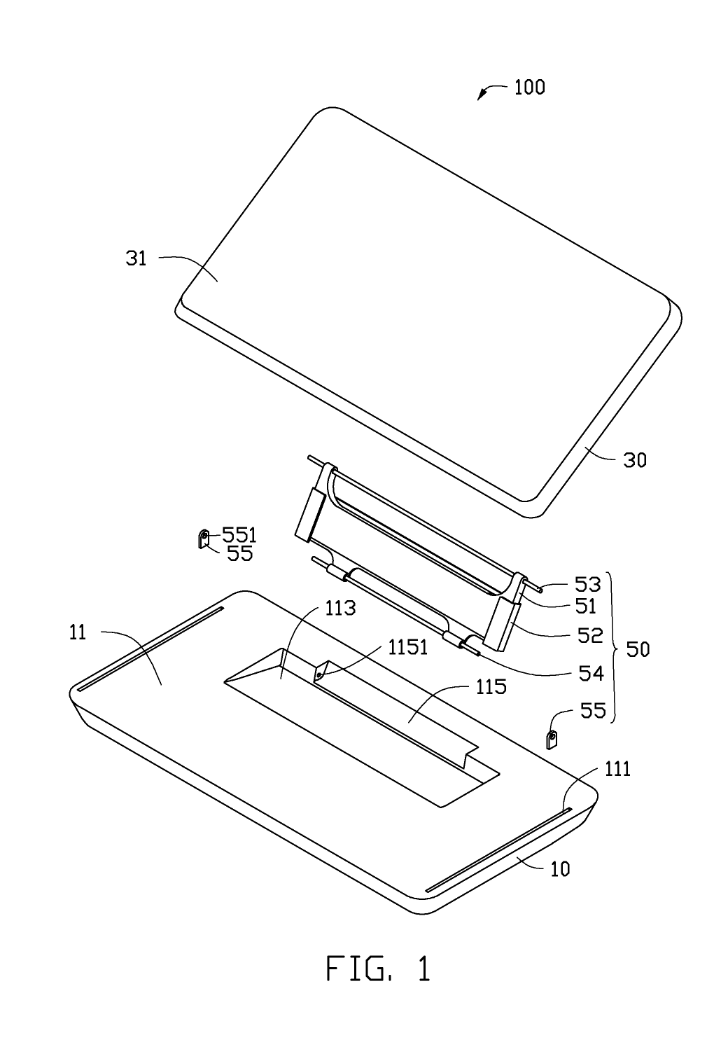

FIG. 1 is an exemplary embodiment of a portable electronic device 100, such as a cellular phone or other electronic device where an adjustable display is needed. The portable electronic device 100 includes a base 10, a cover 30, and an adjusting mechanism 50. The cover 30 carries a display 31 on one surface thereof. Opposite ends of the adjusting mechanism 50 rotatably connect the base 10 to the cover 30. The adjusting mechanism 50 allows the cover 30 to slide and rotate relative to the base 10.

The cover 30 slides on an engaging surface 11 of the base 10. A plurality of input buttons or keys (not shown) may be installed on the engaging surface 11. Two parallel opposite edges of the engaging surface 11 each define a slot 111. The engaging surface 11 defines a receiving space 113 and a bore 115 communicating with the receiving space 113. A depth of the receiving space 113 gradually increases toward the bore 115. A receiving hole 1151 is defined in each of two opposite sides of the bore 115.

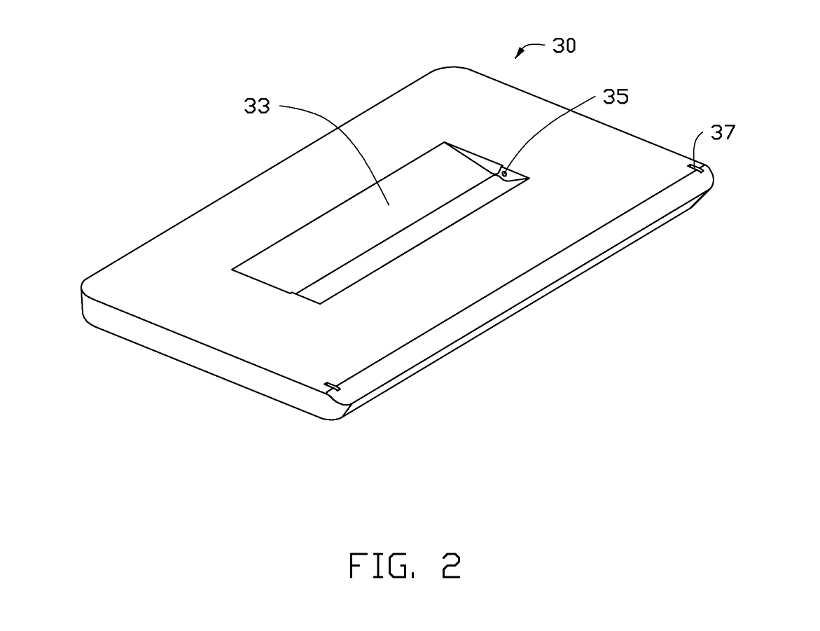

In this exemplary embodiment, the display 31 is a touch-screen. Referring to FIG. 2, the surface of the cover 30 opposite display 31 defines a receiving cavity 33 having two connecting holes 35 in the surface. The two connecting holes 35 are arranged in and communicate with opposite sides of the receiving cavity 33. Two parallel opposite edges of the cover 30 define cutouts 37.

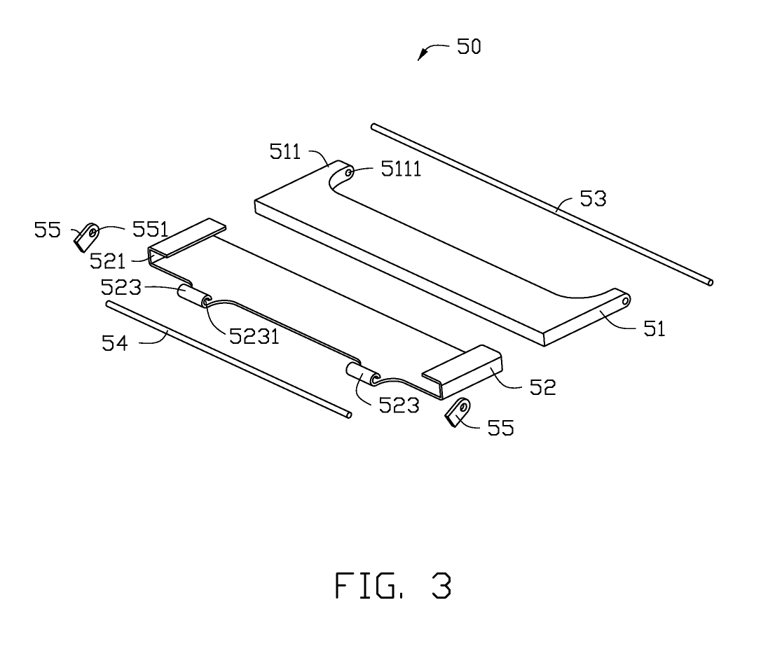

Referring to FIG. 3, the adjusting mechanism 50 includes a connecting plate 51, a frame 52, a first shaft 53, a second shaft 54, and two knuckles 55. A projection 511 extends from each end of the connecting plate 51 and in the same direction. The two projections 511 are parallel to each other and each define a through hole 5111 to receive the first shaft 53 and secure to the connecting holes 35. One side of the connecting plate 51 is pivotably connected to the cover 30 by the first shaft 53 and the two through holes 5111. A rail 521 perpendicularly projects from each end of the frame 52 to receive the connecting plate 51. The second shaft 54 is for pivotably connecting the frame 52 to the base 10 through the receiving holes 1151. The cover 30 slides on the base 10 by the two knuckles 55 being received in corresponding slots 111.

Two hinge joints 523 perpendicularly extend from one edge of the frame 52. Each of the two hinge joints 523 defines an opening 5231 to allow the second shaft 54 to pass therethrough. In the exemplary embodiment, the frame 52 is produced by, for example, means of plastic molding or punching. Each knuckle 55 defines a receiving bore 551 to be pivotably connected to in the cover 30.

During assembly, one end of each knuckle 55 is slidably received in its corresponding slot 111 and secured to the base 10 by a suitable stopper or pin (not shown). The knuckles 55 also may undergo a modification process by heat to form a stopper portion. The other end of each knuckle 55 extends out of the slot 111 and extends perpendicularly beyond the engaging surface 11.

Then the connecting plate 51 is slidably received in the rails 521 of the frame 52. The opposite ends of the second shaft 54 pass the corresponding openings 5231 and rotatably received in the receiving holes 1151 so that the frame 52 is rotatably connected to the base 10. The cover 30 covers and shields the engaging surface 11 so that the buttons or keys are shielded and protected.

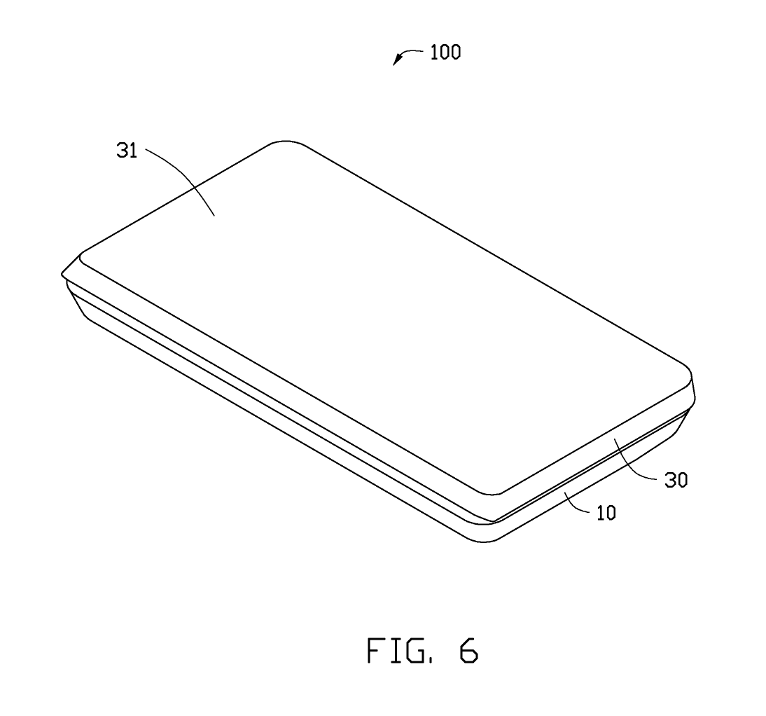

Next, the other end of the knuckles 55 are rotatably received in the cutouts 37 and secured to the cover 30 by a suitable pin or hinge type fastener (not shown), through the receiving bores 551. Thus, the portable electronic device 100 is assembled, as shown in FIG. 6. When closed, the adjusting mechanism 50 is received in the receiving space 113, the bore 115, and the receiving cavity 33. The cover 30 can stay on the base 10 by friction between the cover 30 and the base 10, or a magnetic force or a locking mechanism (neither shown).

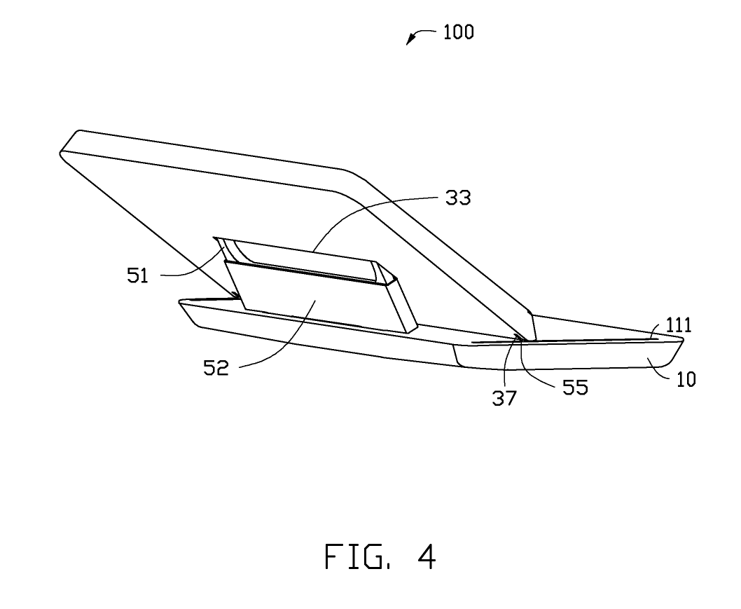

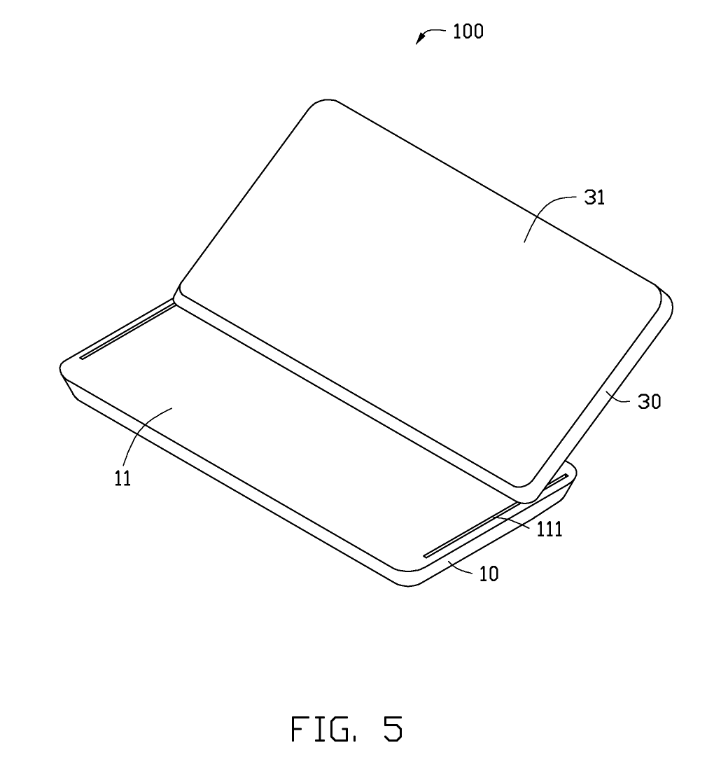

Referring to FIG. 4 through FIG. 6, to adjust the display 31 relative to the base 10 or expose the engaging surface 11, the cover 30 is pushed to slide along the engaging surface 11 by the user. When the cover 30 slides, the connecting plate 51 is pivotably lifted by the first shaft 53 and slides along the rails 521 of the frame 52. The frame 52 is pivotably lifted by the connecting plate 51 and rotates relative to the base 10 by the second shaft 54. During the opening process, one side of the cover 30 is lifted and rotates relative to the base 10, the other end of the cover 30 is retained and slides on the engaging surface 11 by the knuckles 55 sliding along the slots 111. The cover 30 slides along the engaging surface 11 until the knuckles 55 slide to the ends of the slots 111. At the same time, the connecting plate 51 slides along the rails 521 of the frame 52 and the adjusting mechanism 50 extends.

The closing process of the portable electronic device 100 is substantially opposite to the opening process, during the closing process, the connecting plate 51 slides along the rails 521 of the frame 52 and the adjusting mechanism 50 retracts, the distance between the opposite ends of the adjusting mechanism 50 decreases.

It is to be understood that the first shaft 53 and the second shaft 54 can be replaced by pins and/or hinges. Furthermore, the receiving space 113 and the bore 115 in the base 10, or the receiving cavity 33 in the cover 30 may be omitted.

The cover 30 slides on and rotates relative to the base 10, the display 31 on the cover 30 may be adjusted to a preferred position by the user in open state. The engaging surface 11 is covered and shielded by the cover 30 in closed state, thus, it is convenient to use.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A portable electronic device comprising:
a base;
a cover;
a connecting plate, the connecting plate pivotably connected to the cover; and
a frame pivotably connected to the cover and slidably receiving the connecting plate therein, one edge of the cover riding on the base and the other edge of the cover lifted from the base.

2. The portable electronic device as claimed in claim 1, further comprising a knuckle, one end of the knuckle slidably received in the base and the other end of the knuckle rotatably received in the cover.

3. The portable electronic device as claimed in claim 1, wherein two rails project from opposite ends of the frame, in which the connecting plate is slidably received.

4. The portable electronic device as claimed in claim 3, wherein the portable electronic device further comprises a first shaft, two projections extend from one side of the connecting plate, each projection defines a through hole to allow the first shaft to pass therethrough and be pivotably attached to the base.

5. The portable electronic device as claimed in claim 4, wherein the portable electronic device further comprise a second shaft, two hinge joints, each with an opening therethrough, formed on one side of the frame, the second shaft passes through the openings and is rotatably received in the base.

6. The portable electronic device as claimed in claim 1, wherein the base defines a receiving space, the cover defines a receiving cavity, the connecting plate and the frame can be received in the receiving space and the receiving cavity.

7. A portable electronic device comprising:
a base including an engaging surface;
a cover;
a connecting plate, the connecting plate pivotably connected to the cover; and
a frame pivotably connected to the cover and slidably receiving the connecting plate therein, one edge of the cover sliding along the engaging surface and the other edge of the cover rotating upwards from the engaging surface during opening.

8. The portable electronic device as claimed in claim 7, further comprising a knuckle, one end of the knuckle slidably received in the base and the other end of the knuckle rotatably received in the cover.

9. The portable electronic device as claimed in claim 7, wherein two rails project from opposite ends of the frame, in which the connecting plate is slidably received.

10. The portable electronic device as claimed in claim 9, wherein the portable electronic device further comprises a first shaft, two projections extend from one side of the connecting plate, each projection defines a through hole to allow the first shaft to pass therethrough and be pivotably attached to the base.

11. The portable electronic device as claimed in claim 10, wherein the portable electronic device further comprise a second shaft, two hinge joints, each with an opening therethrough, formed on one side of the frame, the second shaft passes through the openings and is rotatably received in the base.

12. The portable electronic device as claimed in claim 7, wherein the base defines a receiving space, the cover defines a receiving cavity, the connecting plate and the frame can be received in the receiving space and the receiving cavity.

13. A portable electronic device comprising:
a base;
a cover;
an adjusting mechanism, one side of the adjusting mechanism rotatably attached to the base and the other end of the adjusting mechanism rotatably attached to the cover, the adjusting mechanism expanding during opening, one edge of the cover sliding one the base and the other edge of the cover lifted from the base by the adjusting mechanism.

14. The portable electronic device as claimed in claim 13, the adjusting mechanism comprising a connecting plate and a frame, one of the connecting plate is rotatably attached to the cover, the other end of the connecting plate is slidably received in the frame, the frame is rotatably attached to the base.

15. The portable electronic device as claimed in claim 14, the adjusting mechanism further comprises a knuckle, one end of the knuckle is slidably received in the base and the other end of the knuckle rotatably received in the cover.

16. The portable electronic device as claimed in claim 14, wherein two rails project from opposite ends of the frame, in which the connecting plate is slidably received.

17. The portable electronic device as claimed in claim 16, wherein the portable electronic device further comprises a first shaft, two projections extend from one side of the connecting plate, each projection defines a through hole to allow the first shaft to pass therethrough and be pivotably attached to the base.

18. The portable electronic device as claimed in claim 17, wherein the portable electronic device further comprise a second shaft, two hinge joints, each with an opening therethrough, formed on one side of the frame, the second shaft passes through the openings and is rotatably received in the base.

19. The portable electronic device as claimed in claim 14, wherein the base defines a receiving space, the cover defines a receiving cavity, the connecting plate and the frame can be received in the receiving space and the receiving cavity.
